(19) United States
(12) Patent Application Publication
(10) Pub. No.: US 2013/0200530 A1
(43) Pub. Date: Aug. 8, 2013

(54) Semiconductor Packages Including a Plurality of Stacked Semiconductor Chips

(71) Applicants: In-sang Song, Yongin-si (KR); Jin-ho Kim, Cheonan-si (KR)

(72) Inventors: In-sang Song, Yongin-si (KR); Jin-ho Kim, Cheonan-si (KR)

(73) Assignee: Samsung Electronics Co., Ltd., Suwon-si (KR)

(21) Appl. No.: 13/752,735

(22) Filed: Jan. 29, 2013

(30) Foreign Application Priority Data
Feb. 3, 2012 (KR) 10-2012-0011291

(51) Int. Cl. H01L 25/07

(52) U.S. Cl. CPC H01L 25/074
USPC 257/777

(57) ABSTRACT

Semiconductor packages including a plurality of semiconductor chips are provided. The semiconductor package includes a semiconductor base frame; a first semiconductor chip stacked on the semiconductor base frame and having an upper surface that has a first area; a second semiconductor chip stacked on the first semiconductor chip and having an upper surface that has a second area larger than the first area; a first adhesive tape attached to a lower surface of the first semiconductor chip and a second adhesive tape attached to a lower surface of the second semiconductor chip; and first and second bonding wires that connect the first semiconductor chip and the second semiconductor chip to the semiconductor base frame, respectively. The first bonding wire bends through the second adhesive tape and is connected to a portion of the semiconductor base frame, which is located below the lower surface of the second semiconductor chip.

### CLAIM OF PRIORITY

This application claims priority to Korean Patent Application No. 10-2012-0011291, filed Feb. 3, 2012, the disclosure of which is hereby incorporated herein in its entirety by reference.

### FIELD

The inventive concept relates to a semiconductor package, and more particularly, to a semiconductor package including a plurality of semiconductor chips.

### BACKGROUND

Electronic equipment has become increasingly smaller and lighter due to rapid progress in electronic industries and user demand. Thus, high integration of semiconductor devices that are key components of the electronic equipment may be required. Furthermore, miniaturization and multi-functionality may be requires as mobile products continue to be developed.

Accordingly, in order to provide multifunction semiconductor packages, various semiconductor chips having different functions into a single semiconductor package have been investigated. However, in cases where various semiconductor chips are included in a single semiconductor package, performance degradation and increased cost may occur due to an increase in electrical paths of each semiconductor chip.

### SUMMARY

Some embodiments of the present inventive concept provide semiconductor package including a semiconductor base frame; a first semiconductor chip on the semiconductor base frame, an upper surface of the first semiconductor chip having a first area; a second semiconductor chip on the first semiconductor chip, an upper surface of the second semiconductor having a second area larger than the first area; a first adhesive tape attached to a lower surface of the first semiconductor chip; a second adhesive tape attached to a lower surface of the second semiconductor chip; a first bonding wire connecting the first semiconductor chip to the semiconductor base frame; and a second bonding wire connecting the second semiconductor chip to the semiconductor base frame. The first bonding wire extends spaced apart from the lower surface of the second semiconductor chip, bends through the second adhesive tape and is connected to a portion of the semiconductor base frame located below the lower surface of the second semiconductor chip.

In further embodiments, the semiconductor package may include at least one second additional semiconductor chip stacked on the second semiconductor chip, an upper surface of the at least one second additional semiconductor chip having the second area and an operation speed substantially equal to an operation speed of the second semiconductor chip; and a second additional adhesive tape attached to a lower surface of the at least one second additional semiconductor chip.

In still further embodiments, the at least one second additional semiconductor chip may have a stair shape on the second semiconductor chip and a thickness of the second additional adhesive tape is less than a thickness of the second adhesive tape.

In some embodiments, the at least one second additional semiconductor chip and the second semiconductor chip may be lined up in a vertical direction with respect to the semiconductor base frame and the second additional adhesive tape may have a thickness substantially the same as a thickness of the second adhesive tape.

In further embodiments, the semiconductor package may include a third semiconductor chip on the second semiconductor chip. The third semiconductor chip may have a third adhesive tape connected to a lower surface thereof configured to attach to the second semiconductor chip. An area of an upper surface of the third semiconductor chip may be smaller than the second area and a thickness of the third adhesive tape may be less than a thickness of the second adhesive tape.

In still further embodiments, the first semiconductor chip may be one of a static random access memory (SRAM) chip and a dynamic random access memory (DRAM) chip, the second semiconductor chip may be a flash memory chip and the third semiconductor chip may be a control semiconductor chip configured to control the second semiconductor chip.

In some embodiments, an operation speed of the first semiconductor chip may be faster than an operation speed of the second semiconductor chip.

In further embodiments, one portion of the first bonding wire located above the upper surface of the second semiconductor chip may penetrate the second adhesive tape and may have a length shorter than a length of a second portion of the first bonding wire.

In still further embodiments, a thickness of the first adhesive tape may be less than a thickness of the second adhesive tape.

In some embodiments, the semiconductor package may further include at least one first additional semiconductor chip between the first semiconductor chip and the semiconductor base frame. The at least one first additional semiconductor chip may have an upper surface having the first area and an operation speed substantially equal to an operation speed of the first semiconductor chip. A first additional adhesive tape may be attached to a lower surface of the at least one first additional semiconductor chip.

In further embodiments, the at least one first additional semiconductor chip and the first semiconductor chip may be a stair shape and a thickness of the at least one first additional adhesive tape and a thickness of the first adhesive tape may be less than a thickness of the second adhesive tape.

In still further embodiments, the at least one first additional semiconductor chip and the first semiconductor chip may completely overlap each other on the semiconductor base frame and n the first adhesive tape may have a thickness substantially equal to a thickness of the second adhesive tape.

In some embodiments, the first bonding wire is below the lower surface of the second semiconductor chip.

In further embodiments, the first bonding wire may be connected to the semiconductor base frame by a stitch bond on the semiconductor base frame and a security bump may be further attached on the stitch bond of the first bonding wire.

Still further embodiments provide semiconductor packages including a first semiconductor chip attached to a semiconductor base frame using a first adhesive tape; a second semiconductor chip attached to the first semiconductor chip using a second adhesive tape having a thickness larger than a thickness of the first adhesive tape, an upper surface of the second semiconductor chip having an area larger than an area of the first semiconductor chip and an operation speed that is slower than an operation speed of the first semiconductor chip; a first bonding wire configured to connect the first semiconductor chip to the semiconductor base frame; and a second bonding wire configured to connect the second semiconductor chip to the semiconductor base frame, wherein the first bonding wire is located below the lower surface of the second semiconductor chip.

Some embodiments provide semiconductor packages including a semiconductor base frame; a first semiconductor chip on the semiconductor base frame, an upper surface of the first semiconductor chip having a first area; a second semiconductor chip on the first semiconductor chip, an upper surface of the second semiconductor chip having a second area larger than the first area; a first adhesive tape attached to a lower surface of the first semiconductor chip; a second adhesive tape attached to a lower surface of the second semiconductor chip; a first bonding wire forming a stitch bond on the semiconductor base frame to connect the first semiconductor chip to the semiconductor base frame; and a second bonding wire forming a stitch bond on the semiconductor base frame to connect the second semiconductor chip to the semiconductor base frame, wherein a security bump is further attached on the stitch bond of the first bonding wire.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross section illustrating a semiconductor package according to some embodiments of the inventive concept.

FIG. 2 is a cross section illustrating a semiconductor package according to some embodiments of the inventive concept.

FIG. 3 is a cross section illustrating a semiconductor package according to some embodiments of the inventive concept.

FIG. 4 is a cross section illustrating a semiconductor package according to some embodiments of the inventive concept.

FIG. 5 is a cross section illustrating a semiconductor package according to some embodiments of the inventive concept.

FIGS. 6 through 8 are cross sections illustrating processing steps in the fabrication of semiconductor packages illustrated in FIG. 1.

FIGS. 9 through 11 are cross sections illustrating processing steps in the fabrication of semiconductor packages illustrated in FIG. 2.

FIGS. 12 through 15 are cross sections illustrating processing steps in the fabrication of semiconductors package illustrated in FIG. 3.

FIGS. 16 and 17 are cross sections illustrating processing steps in the fabrication of semiconductor packages illustrated in FIG. 4.

FIGS. 18 through 20 are cross sections illustrating processing steps in the fabrication of semiconductor packages illustrated in FIG. 5.

FIG. 21 is a cross section illustrating a first bonding wire according to some embodiments of the inventive concept.

FIG. 22 is a cross section illustrating a first finger bond connected to a first bonding wire according to some embodiments of the inventive concept.

FIG. 23 is a cross section illustrating a second finger bond connected to a second bonding wire according to some embodiments of the inventive concept.

### DETAILED DESCRIPTION OF THE EMBODIMENTS

The inventive concept will now be described more fully with reference to the accompanying drawings, in which exemplary embodiments of the inventive concept are shown. The inventive concept may, however, be embodied in many different forms by one of ordinary skill in the art without departing from the technical teaching of the inventive concept. In other words, particular structural and functional description of the inventive concept are provided in descriptive sense only; various changes in form and details may be made therein and thus should not be construed as being limited to the embodiments set forth herein. As the inventive concept is not limited to the embodiments described in the present description, and thus it should not be understood that the inventive concept includes every kind of variation examples or alternative equivalents included in the spirit and scope of the inventive concept.

It will be understood that when an element is referred to as being “connected to”, or “contacting” another element throughout the specification, it can be directly “connected to” or “contacting” the other element, or intervening elements may also be present. On the other hand, when a component is referred to as being “directly connected to” or “directly contacting” another element, it will be understood that no intervening element is present. Other words used to describe the relationship between elements should be interpreted in a like fashion (e.g., “between,” versus “directly between,” “adjacent,” versus “directly adjacent,” etc.).

In the present description, terms such as ‘first’, ‘second’, etc. are used to describe various elements. However, it is obvious that the elements should not be defined by these terms. The terms are used only for distinguishing one element from another element. For example, a first element which could be termed a second element, and similarly, a second element may be termed a first element, without departing from the teaching of the inventive concept.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art.

Like reference numerals in the drawings denote like elements or corresponding elements that are replaceable within the scope of the technical spirit of the inventive concept.

As used herein, the term “and/or” includes any and all combinations of one or more of the associated listed items. Expressions such as “at least one of” when preceding a list of elements, modify the entire list of elements and do not modify the individual elements of the list.

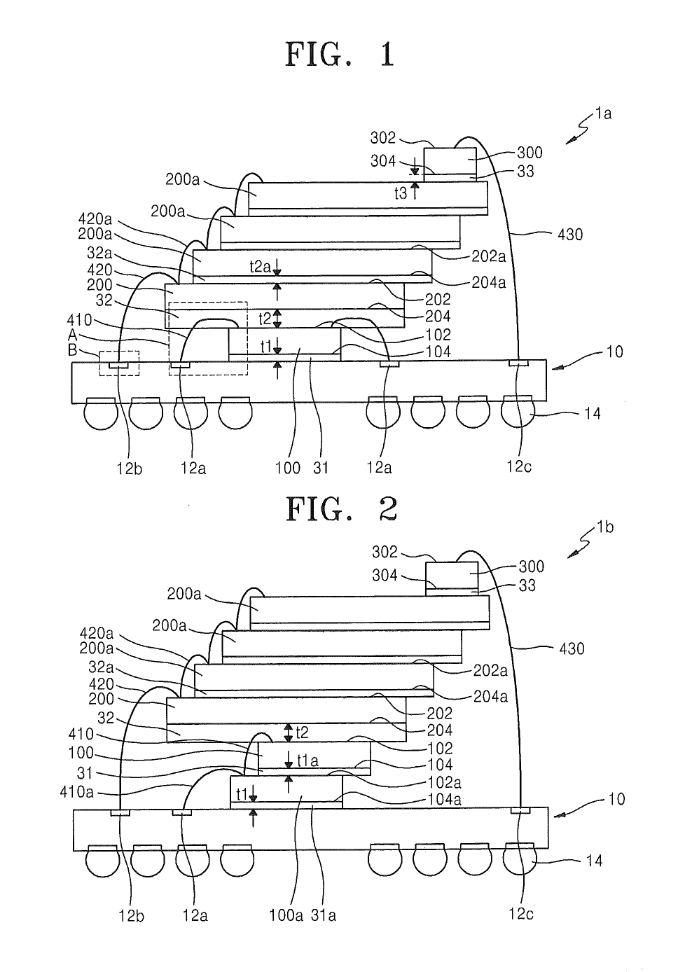

As will be discussed herein with respect to FIGS. 1 though 23, some embodiments of the present inventive concept provide semiconductor packages that include a plurality of semiconductor chips and high capacity, multi-functionality, and high-speed operation to address problems discussed above in the background of the inventive concept.

Referring first to FIG. 1, a cross section illustrating a semiconductor package 1a according to some embodiments of the inventive concept will be discussed. As illustrated in FIG. 1, the semiconductor package 1a includes a first semiconductor chip 100 and a second semiconductor chip 200 stacked on a semiconductor base frame 10. The upper surface 102 of the semiconductor chip 100 may have a first area, and the upper surface 202 of the semiconductor chip 200 may have a second area that is larger than the first area. In some embodiments, the second semiconductor chip 200 may be stacked on the first semiconductor chip 100 to completely cover the upper surface 102 of the first semiconductor chip 100.

A first adhesive tape 31 may be attached on the lower surface 104 of the first semiconductor chip 100. Similarly, a second adhesive tape 32 may be attached on the lower surface 204 of the second semiconductor chip 200. The first adhesive tape 31 and the second adhesive tape 32 may completely cover the lower surface 104 of the first semiconductor chip 100 and the lower surface 204 of the second semiconductor chip 200, respectively. The first adhesive tape 31 and the second adhesive tape 32 may have the first area and the second area, respectively. The first semiconductor chip 100 may be attached on the semiconductor base frame 10 by the first adhesive tape 31.

The second semiconductor chip 200 may be stacked on the first semiconductor chip 100 through the second adhesive tape 32 attached on the lower surface of the second semiconductor chip 200. The second adhesive tape 32 may completely cover the upper surface 102 of the first semiconductor chip 100 while contacting the upper surface 102 of the first semiconductor chip 100.

The semiconductor base frame 10 may be, for example, a printed circuit board (PCB) or a lead frame. If the semiconductor base frame 10 is a PCB, the semiconductor base frame 10 may be a base substrate, a conductive pattern, a solder resist layer, and the like. First through third finger bonds 12a, 12b, and 12c that are exposed to the outside of the semiconductor base frame 10 may be on a first side of the semiconductor base frame 10. An external terminal portion 14 may be on a second side of the semiconductor base frame 10, opposite the first side of the semiconductor base frame 10. However, if the semiconductor base frame 10 is a lead frame, leads that correspond to the finger bonds 12a, 12b, and 12c may be present instead of the finger bonds 12a, 12b and 12C.

A first bonding wire 410 and a second boding wire 420 may be connected between the first semiconductor chip 100 and the semiconductor base frame 10 and between the second semiconductor chip 200 and the semiconductor base frame 10, respectively, to transmit a power supply voltage, signals, and the like. The first bonding wire 410 may connect a pad on the upper surface 102 of the first semiconductor chip 100 to the first finger bond 12a in the semiconductor base frame 10. The second bonding wire 420 may connect a pad on the upper surface 202 of the second semiconductor chip 200 to the second finger bond 12b in the semiconductor base frame 10.

The first bonding wire 410 may bend after extending spaced apart from the lower surface 204 of the second semiconductor chip 200 through the inside of the second adhesive tape 32 covering the upper surface 102 of the first semiconductor chip 100, and may be connected to the first finger bond 12a of the semiconductor base frame 10. In these embodiments, the first finger bond 12a may be in a portion of the semiconductor base frame 10, which is located below the lower surface 204 of the second semiconductor chip 200. In addition, the first bonding wire 410 may be disposed below the lower surface 204 of the second semiconductor chip 200. Alternatively, at least one portion of the first finger bond 12a may be in a portion of the semiconductor base frame 10, which is located below the lower surface 204 of the second semiconductor chip 200. In these embodiments, only a portion of the first bonding wire 410 may be disposed below the lower surface 204 of the second semiconductor chip 200.

In other words, the first bonding wire 410 may penetrate a portion of the second adhesive tape 32. A portion of the first bonding wire 410, which is located above the upper surface 102 of the first semiconductor chip 100, penetrates the second adhesive tape 32, i.e., is formed inside of the second adhesive tape 32, may have a length shorter than that of a different portion of the first bonding wire 410, which is not located above the upper surface 102 of the first semiconductor chip 100.

A plurality of second semiconductor chips 200 and 200a may be stacked on the first semiconductor chip 100. If the plurality of second semiconductor chips 200 and 200a are stacked on the first semiconductor chip, the second semiconductor chips 200a additionally stacked on the second semiconductor chip 200 that is stacked closest to and on the first semiconductor chip 100 may be referred to as second additional semiconductor chips 200a for convenience of explanation. In other words, the second additional semiconductor chips 200a may be the same kind of semiconductor chips of which upper surface areas and operation speeds are equal to those of the second semiconductor chip 200. The area of an upper surface 202a of each of the second additional semiconductor chips 200a may be the second area. Although three second additional semiconductor chips 200a are illustrated in FIG. 1, embodiments of the present inventive concept are not limited to this configuration. For example, one, two, or more than four second additional semiconductor chips 200a may be stacked without departing from the scope of the present inventive concept.

The second additional semiconductor chips 200a may be stacked in a stair shape to expose a portion of the second semiconductor chip 200, which is located under the second additional semiconductor chips 200a, and expose portions of the second additional semiconductor chips 200a. A second additional adhesive tape 32a may be attached to the lower surface 204a of each of the second additional semiconductor chips 200a.

If the second additional semiconductor chips 200a are stacked in a stair shape, a second additional bonding wire 420a may be formed to connect an exposed portion of the second semiconductor chip 200 to a pad on the upper surface 202a of a second additional semiconductor chip 200a that is located directly over the second semiconductor chip 200 or connect an exposed portion of a lower second additional semiconductor chip 200a to a pad on the upper surface of an upper second additional semiconductor chip 200a that is located directly over the lower second additional semiconductor chip 200a. The second additional bonding wire 420a and the second bonding wire 420 may be formed together to have a single wire form.

A third semiconductor chip 300 may be further stacked on the second semiconductor chip 200 or one of the second additional semiconductor chips 200a. A third adhesive tape 33 may be attached on the lower surface 304 of the third semiconductor chip 300. A third bonding wire 430 may be formed to connect a pad on the upper surface 302 of the third semiconductor chip 300 to the third finger bond 12c of the semiconductor base frame 10.

The first bonding wire 410 may be connected to the first finger bond 12a by a stitch bond on the first finger bond 12a, and a security bump may be provided on the stitch bond which is formed by the first bonding wire 410.

The second bonding wire 420 may be connected to the second finger bond 12b by a stitch bond on the second finger bond 12b, and a security bump may not be provided on the stitch bond which is formed by the second bonding wire 420.

In other words, the first bonding wire 410 may be connected to the first finger bond 12a using a stitch bond and a security bump, and the second bonding wire 420 may be connected to the second finger bond 12b using only a stitch bond.

A bonding wire, which extends through the inside of one of the adhesive tapes 31, 32, and 33, extends to protrude through the lower surface of the one of the adhesive tapes 31, 32, and 33, and then is connected to one of the finger bonds 12a, 12b, and 12c, i.e., the first bonding wire 410, is connected to the first finger bond 12a by a stitch bond on the first finger bond 12a, and a security bump may be further provided on the stitch bond. However, bonding wires, which extend without passing through the insides of the adhesive tapes 31, 32, and 33 and then are connected to one of the finger bonds 12a, 12b, and 12c, i.e., the second and third bonding wires 420 and 430, are connected to the second and third finger bonds 12b and 12c, respectively, by only a stitch bond. Details with respect to these aspects of embodiments discussed herein will be provided below with respect to FIGS. 21 through 23.

The thickness t2 of the second adhesive tape 32 may be larger than the thickness t1 of the first adhesive tape 31, the thickness t2a of the second additional adhesive tape 32a, or the thickness t3 of the third adhesive tape 33. In these embodiments, the first bonding wire 410 penetrates the second adhesive tape 32, and may extend spaced apart from the second semiconductor chip 200 when extending along the lower surface 204 of the second semiconductor chip 200.

For example, the thickness t2 of the second adhesive tape 32 may be 60 μm, and the thickness t1 of the first adhesive tape 31, the thickness t2a of the second additional adhesive tape 32a, or the thickness t3 of the third adhesive tape 33 may be 20 μm.

The operation speed of the first semiconductor chip 100 may be faster than that of the second semiconductor chip 200. For example, the first semiconductor chip 100 may be a high speed memory chip, such as a static random access memory (SRAM) or a dynamic random access memory (DRAM). The second semiconductor chip 200 may be a low speed memory chip such as a flash memory chip. The third semiconductor chip 300 may be, for example, a control semiconductor chip for controlling the second semiconductor chip 200. When the second semiconductor chip 200 is a flash memory chip, the third semiconductor chip 300 may be a control semiconductor chip for performing wear-leveling, an error correcting code (ECC), or a defective block control.

For example, when the second semiconductor chip 200 is a relatively low speed semiconductor chip for storing high capacity data and the first semiconductor chip 100 is a relatively high speed semiconductor chip for storing low capacity data and performing a cache operation, the length of the first bonding wire 410 that is connected to the first semiconductor chip 100 may be shorter than that of the second bonding wire 420 that is connected to the second semiconductor chip 200, by disposing the first semiconductor chip 100 closer to the semiconductor base frame 10 compared to the second semiconductor chip 200. Thus, since an electrical path from the first semiconductor chip 100 to the external terminal portion 14 may become short, the first semiconductor chip 100 may be easy to operate at a relatively high speed compared to the second semiconductor chip 200.

Furthermore, since the first bonding wire 410 is formed to be located below the lower surface 204 of the second semiconductor chip 200, an increase in the volume of the semiconductor package 1a due to the first bonding wire 410 may not occur.

The first semiconductor chip 100 and the second semiconductor chip 200 may not be electrically connected to each other in the semiconductor package 1a. In other words, the first bonding wire 410 and the second bonding wire 420 that are connected to the first semiconductor chip 100 and the second semiconductor chip 200, respectively, may not be electrically connected through the semiconductor base frame 10 to each other, but may be connected to the external terminal portions 14 electrically insulated from each other. In these embodiments, the first semiconductor chip 100 and the second semiconductor chip 200 may be used for separate purposes by a system or a motherboard to which the semiconductor package 1a is attached, and the semiconductor package 1a may be used as a multifunction package.

Referring now to FIG. 2, a cross section illustrating a semiconductor package 1b according to some embodiments of the inventive concept will be discussed. Like reference numerals in the drawings denote like elements throughout the specification. Thus, details discussed with respect to like elements in FIG. 1 will not be repeated herein in the interest of brevity. As illustrated in FIG. 2, the semiconductor package 1b may include a first semiconductor chip 100, a second semiconductor chip 200, a second additional semiconductor chip 200a, and a third semiconductor chip 300.

Comparing the semiconductor package 1b illustrated in FIG. 2 to the semiconductor package 1a illustrated in FIG. 1, a plurality of first semiconductor chips 100 and 100a may be stacked under the second semiconductor chip 200. When the plurality of first semiconductor chips 100 and 100a and the second semiconductor chip 200 are stacked on a semiconductor base frame 10, the first semiconductor chip 100a disposed under the first semiconductor chip 100 that closest to the second semiconductor chip 200 may be referred to as a first additional semiconductor chip 100a for convenience of explanation. In other words, the first additional semiconductor chip 100a may be the same kind of semiconductor chip of which an upper surface area and an operation speed are equal to those of the first semiconductor chip 100. The area of the upper surface 102a of the first additional semiconductor chip 100a may be the first area. Although one first additional semiconductor chip 100a is illustrated in FIG. 2, embodiments of the present inventive concept are not limited to this configuration. For example, two or more first additional semiconductor chips 100a may be stacked. A first additional adhesive tape 31a may be attached to the lower surface 104a of the first additional semiconductor chip 100a. The first additional adhesive tape 31a may have the same thickness as the first adhesive tape 31.

The first additional semiconductor chip 100a and the first semiconductor chip 100 may be stacked in a stair shape. A first bonding wire 410 may be formed to connect a pad on an exposed portion of the upper surface 102a of the first additional semiconductor chip 100a to a pad on the upper surface 102 of the first semiconductor chip 100, and a first additional bonding wire 410a may be formed to connect a first finger bond 12a of the semiconductor base frame 10 to the pad on the exposed portion of the upper surface 102a of the first additional semiconductor chip 100a. The first additional bonding wire 410a and the first bonding wire 410 may be formed together to have a single wire form.

The first finger bond 12a may be formed in a portion of the semiconductor base frame 10, which is located below the lower surface 204 of the second semiconductor chip 200. Furthermore, the first bonding wire 410 and the additional bonding wire 410a may be disposed completely below the lower surface 204 of the second semiconductor chip 200. Alternatively, at least one portion of the first finger bond 12a may be formed in a portion of the semiconductor base frame 10, which is located below the lower surface 204 of the second semiconductor chip 200. In these embodiments, only a portion of the first bonding wire 410 may be disposed completely below the lower surface 204 of the second semiconductor chip 200.

When, from among the bonding wires 410, 410a, 420, 420a, and 430, there is no bonding wire, which extends through the inside of one of the adhesive tapes 31, 32, and 33, protrudes through the lower surface of the one of the adhesive tapes 31, 32, and 33, and then is connected to one of the finger bonds 12a, 12b, and 12c, the first additional bonding wire 410a, the second bonding wire 420, and the third bonding wire 430 may be connected to the finger bonds 12a, 12b, and 12c, respectively, by only respective stitch bonds.

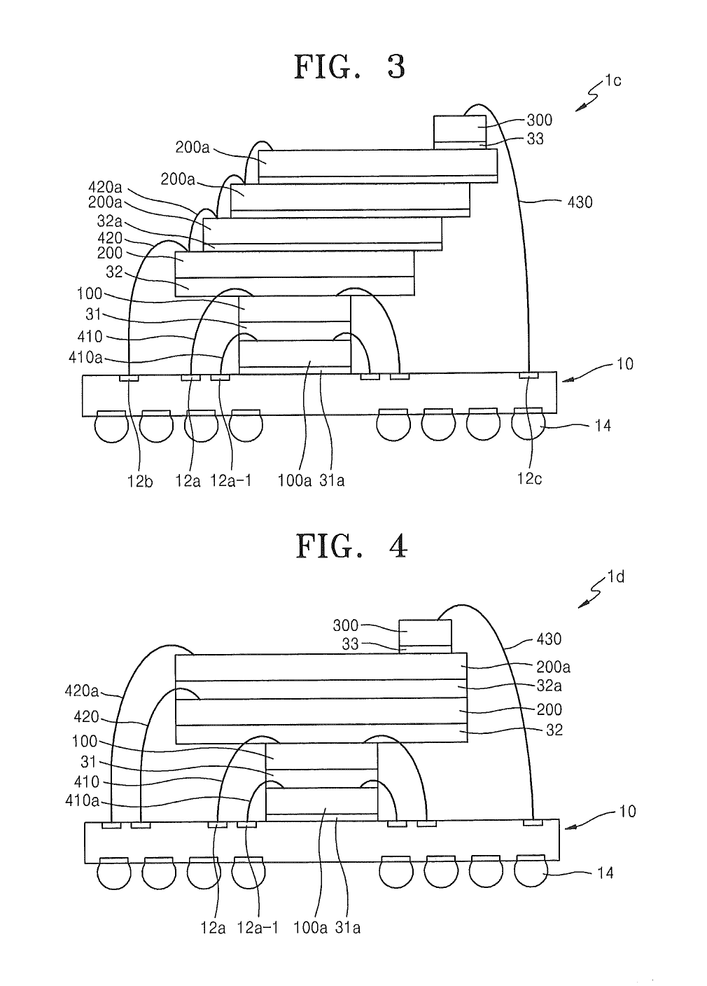

Referring now to FIG. 3, a cross section illustrating a semiconductor package 1c according to some embodiments of the inventive concept will be discussed. Like reference numerals in the drawings denote like elements throughout the specification. Thus, details discussed with respect to like elements in FIGS. 1 and 2 will not be repeated herein in the interest of brevity. As illustrated in FIG. 3, the semiconductor package 1c may include a first semiconductor chip 100, a first additional semiconductor chip 100a, a second semiconductor chip 200, a second additional semiconductor chip 200a, and a third semiconductor chip 300.

Comparing the semiconductor package 1c of FIG. 3 with the semiconductor package 1a illustrated in FIG. 1, a plurality of first semiconductor chips 100 and 100a are stacked to overlap each other on a semiconductor base frame 10. Comparing the semiconductor package 1c of FIG. 3 with the semiconductor package 1b illustrated in FIG. 2, in the semiconductor package 1c shown in FIG. 3, the first semiconductor chip 100 and the first additional semiconductor chip 100a are stacked to be lined up in the vertical direction with respect to the semiconductor base frame 10. Thus, the first semiconductor chip 100 and the first additional semiconductor chip 100a may be stacked to completely overlap each other with respect to the semiconductor base frame 10.

The first additional bonding wire 410a may be connected to a first additional finger bond 12a-1 of the semiconductor base frame 10 through a first adhesive tape 31 attached on the first additional semiconductor chip 100a. Each of the first adhesive tape 31 and a second adhesive tape 32 may have a thickness larger than that of a first additional adhesive tape 31 a so that a first bonding wire 410 and a first additional bonding wire 410a pass through the first adhesive tape 31 and the second adhesive tape 32, respectively. In addition, the first adhesive tape 31 may have a thickness which is equal to the thickness of the second adhesive tape 32.

The first bonding wire 410 may be connected to a first finger bond 12a by a stitch bond on the first finger bond 12a, and a security bump may be provided on the stitch bond which is formed by the first bonding wire 410.

The first additional bonding wire 410a may be connected to the first additional finger bond 12a-1 by a stitch bond on the first additional finger bond 12a-1, and a security bump may not be provided on the stitch bond which is formed by the first additional bonding wire 410a.

The second bonding wire 420 may be connected to a second finger bond 12b by a stitch bond on the second finger bond 12b, and a security bump may not be formed on the stitch bond which is formed by the second bonding wire 420.

In other words, the first bonding wire 410 may be connected to the first finger bond 12a using a stitch bond and a security bump, and the first additional bonding wire 410a and the second bonding wire 420 may be connected to the first additional finger bond 12a-1 and the second finger bond 12b, respectively, by using only a stitch bond,

A bonding wire, which extends through the inside of one of the adhesive tapes 31, 32, and 33, protrudes through the lower surface of the one of the adhesive tapes 31, 32, and 33, and is connected to one of the finger bonds 12a, 12b, and 12c, i.e., the first bonding wire 410, is connected to the first finger bond 12a by a stitch bond, and a security bump may be further provided on the stitch bond. However, bonding wires, each of which extends without passing through the insides of the adhesive tapes 31, 31a, 32, 32a, and 33 and is connected to one of the finger bonds 12a, 12b, and 12c, or which extends through the inside of one of the adhesive tapes 31, 31a, 32, 32a, and 33, protrudes through a side surface of the one of the adhesive tapes 31, 31a, 32, 32a, and 33, and is connected to one of the finger bonds 12a, 12b, and 12c. In other words, the first additional bonding wire 410a, the second bonding wire 420, and the third bonding wire 430, may be connected to the first additional finger bond 12a-1, the second finger bond 12b, and the third finger bond 12c by forming only respective stitch bonds.

Referring now to FIG. 4, a cross section illustrating a semiconductor package 1d according to some embodiments of the inventive concept will be discussed. Like reference numerals in the drawings denote like elements throughout the specification. Thus, details discussed with respect to like elements in FIGS. 1-3 will not be repeated herein in the interest of brevity. Referring to FIG. 4, the semiconductor package 1d may include a first semiconductor chip 100, a first additional semiconductor chip 100a, a second semiconductor chip 200, a second additional semiconductor chip 200a, and a third semiconductor chip 300.

In the semiconductor package 1d illustrated in FIG. 4, the first semiconductor chip 100 and the first additional semiconductor chip 100a are stacked to be lined up in the vertical direction with respect to the semiconductor base frame 10, and, in addition, the second semiconductor chip 200 and the second additional semiconductor chip 200a also may be stacked to be lined up in the vertical direction. Thus, the second semiconductor chip 200 and the second additional semiconductor chip 200a may be stacked to completely overlap each other with respect to the semiconductor base frame 10.

In the case of the semiconductor chips 100, 100a, and 200 on each of which another semiconductor chip is stacked, bonding wires 410, 410a, and 420 may penetrate a first adhesive tape 31, a second adhesive tape 32, and a second additional adhesive tape 32a, respectively. Thus, the first adhesive tape 31, the second adhesive tape 32, and the second additional adhesive tape 32a may have a thickness larger than that of a first additional adhesive tape 31a or a third adhesive tape 33. The first adhesive tape 31, the second adhesive tape 32, and the second additional adhesive tape 32a may have the same thickness.

The first bonding wire 410 may be connected to a first finger bond 12a by a stitch bond on the first finger bond 12a, and a security bump may be provided on the stitch bond. However, the first additional bonding wire 410a, the second bonding wire 420, and the third bonding wire 430 may be connected to a first additional finger bond 12a-1, a second finger bond 12b, and a third finger bond 12c, respectively, by only respective stitch bonds.

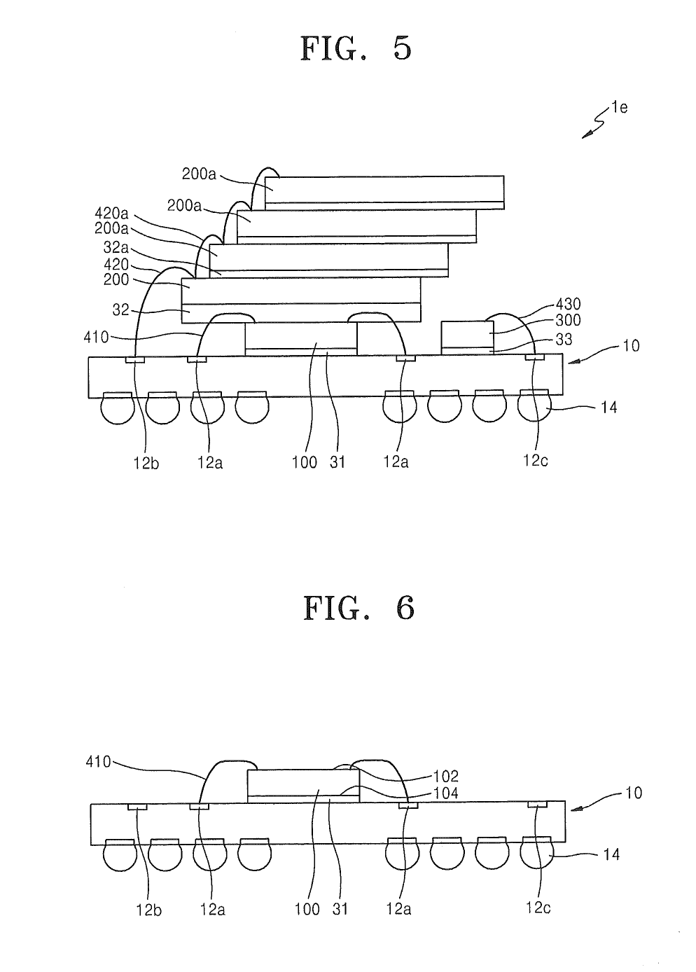

Referring now to FIG. 5, a cross section illustrating a semiconductor package 1e according to some embodiments of the inventive concept will be discussed. Like reference numerals in the drawings denote like elements throughout the specification. Thus, details discussed with respect to like elements in FIG. 1 will not be repeated herein in the interest of brevity.

As illustrated in FIG. 5, in the semiconductor package 1e, a first semiconductor chip 100, a second semiconductor chip 200, and a second additional semiconductor chip 200a are stacked on a semiconductor base frame 10. Comparing the semiconductor package 1e illustrated in FIG. 5 with the semiconductor package 1a illustrated in FIG. 1, a third semiconductor chip 300 may be attached adjacent to and on the semiconductor base frame 10 in the semiconductor package 1e illustrated in FIG. 5. Furthermore, the third semiconductor chip 300 may overlap a stack structure that is formed of a plurality of second semiconductor chips. In other words, the second semiconductor chip 200 and the second additional semiconductor chip 200a. The third semiconductor chip 300 may be disposed in a space under the stack structure that is formed by stacking the second semiconductor chip 200 and the second additional semiconductor chip 200a in a stair shape. Thus, an increase in the volume of the semiconductor package 1e due to the third semiconductor chip 300 may not occur.

A first bonding wire 410 may be connected to a first finger bond 12a by forming a stitch bond on the first finger bond 12a, and a security bump may be on the stitch bond. However, a second bonding wire 420 and a third bonding wire 430 may be connected to a second finger bond 12b and a third finger bond 12c, respectively, by only respective stitch bonds.

Also in the semiconductor packages 1b, 1c, and 1d according to the embodiments shown in FIGS. 2-4, an effect similar to that of the embodiment shown FIG. 5 may be obtained by changing a location of the third semiconductor chip 300.

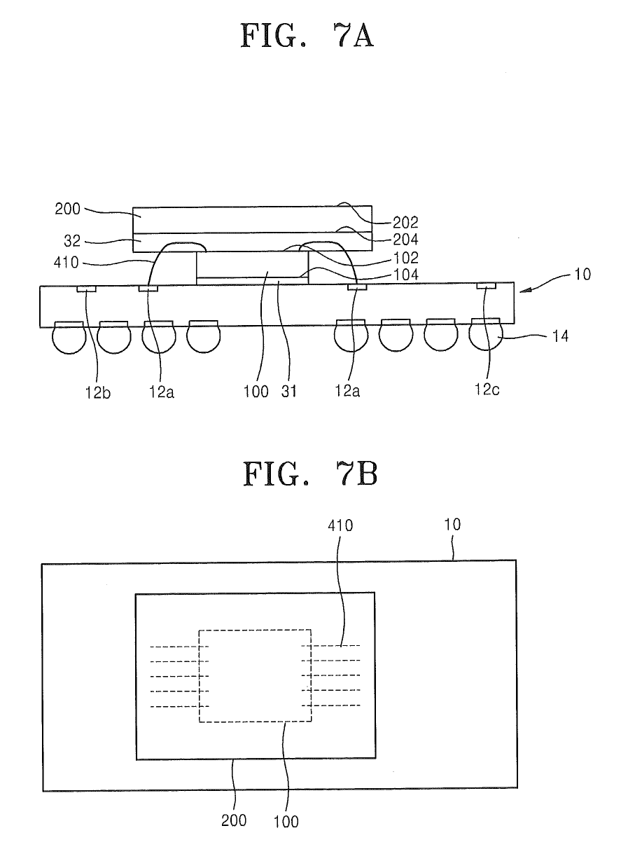

Referring now to FIGS. 6, 7A, and 8, cross sections illustrating processing steps in the fabrication of semiconductor package 1a illustrated in FIG. 1 will be discussed. FIG. 7B is a schematic plan view illustrating a disposition of the first semiconductor chip 100 and the second semiconductor chip 200.

Referring first to FIG. 6 and FIG. 1, the first semiconductor chip 100 may be attached on the semiconductor base frame 10 using the first adhesive tape 31. The first bonding wire 410 is formed to connect a pad formed on the upper surface 102 of the first semiconductor chip 100 to the first finger bond 12a of the semiconductor base frame 10. The first bonding wire 410 is formed so as not to protrude too high with respect to the upper surface 102 of the first semiconductor chip 100 so that the first bonding wire 410 may penetrate the inside of the second adhesive tape 32.

Referring now to FIGS. 7A and 7B and FIG. 1, after forming the first bonding wire 410, the second semiconductor chip 200, in which the second adhesive tape 32 is attached to the lower surface 204 thereof, is attached on the first semiconductor chip 100. The upper surfaces of the first semiconductor chip 100 and the second semiconductor chip 200 may have the first area and the second area, respectively. The second area may be larger than the first area. Thus, the second semiconductor chip 200 may be stacked on the first semiconductor chip 100 to completely cover the upper surface 102 of the first semiconductor chip 100.

When attaching the second semiconductor chip 200 on the first semiconductor chip 100, the first bonding wire 410 extends from a pad formed on the upper surface 102 of the first semiconductor chip 100 to the inside of the second adhesive tape 32, and then extends along the lower surface 204 of the second semiconductor chip 200 in a state in which it is spaced apart from the lower surface 204 of the second semiconductor chip 200. The first bonding wire 410 bends to an opposite direction with respect to the lower surface 204 of the second semiconductor chip 200, extends to protrude through the lower surface of the second adhesive tape 32, and may be connected to the first finger bond 12a of the semiconductor base frame 10. The first bonding wire 410 may be located completely below the lower surface 204 of the second semiconductor chip 200. Alternatively, in some embodiments, only a portion of the first bonding wire 410 may be located completely below the lower surface 204 of the second semiconductor chip 200.

Furthermore, although, in FIG. 7A, the first bonding wire 410 is formed at both sides of the first semiconductor chip 100, the first bonding wire 410 may be formed at all four sides of the first semiconductor chip 100 without departing from the scope of the present inventive concept.

As the first bonding wire 410 extends by a predetermined length along the lower surface 204 of the second semiconductor chip 20 when the first bonding wire 410 penetrates the second adhesive tape 32, the first bonding wire 410 may possibly be prevented from directly contacting the lower surface 200 of the second semiconductor chip 200 due to a variation of the first bonding wire 410 during or after a manufacturing process of the semiconductor package 1a.

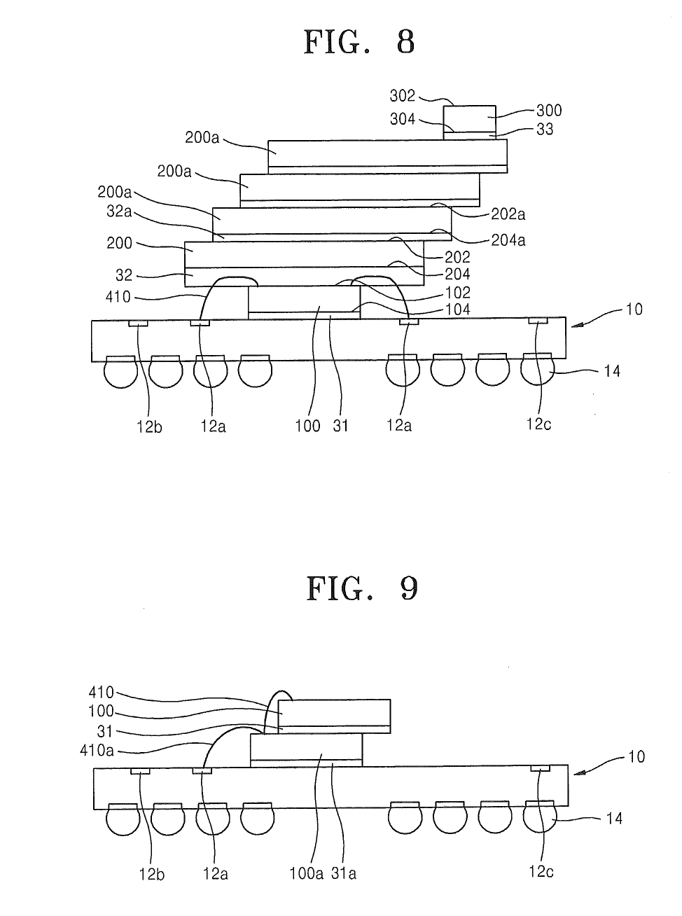

Referring now to FIG. 8 and FIG. 1, at least one second additional semiconductor chip 200a may be stacked on the second semiconductor chip 200 in a stair shape, and the third semiconductor chip 300 may be additionally stacked on the at least one second additional semiconductor chip 200a. The second bonding wire 420, the second additional bonding wire 420a, and the third bonding wire 430 may be formed after stacking the second additional semiconductor chip 200a and the third semiconductor chip 300.

Referring now to FIGS. 9 through 11, cross sections illustrating processing steps in the fabrication of semiconductor packages 1b illustrated in FIG. 2 will be discussed. Referring first to FIGS. 2 and 9, after stacking at least one first additional semiconductor chip 100a and the first semiconductor chip 100 on the semiconductor base frame 10 in a stair shape, the first bonding wire 410 and the first additional bonding wire 410a are formed.

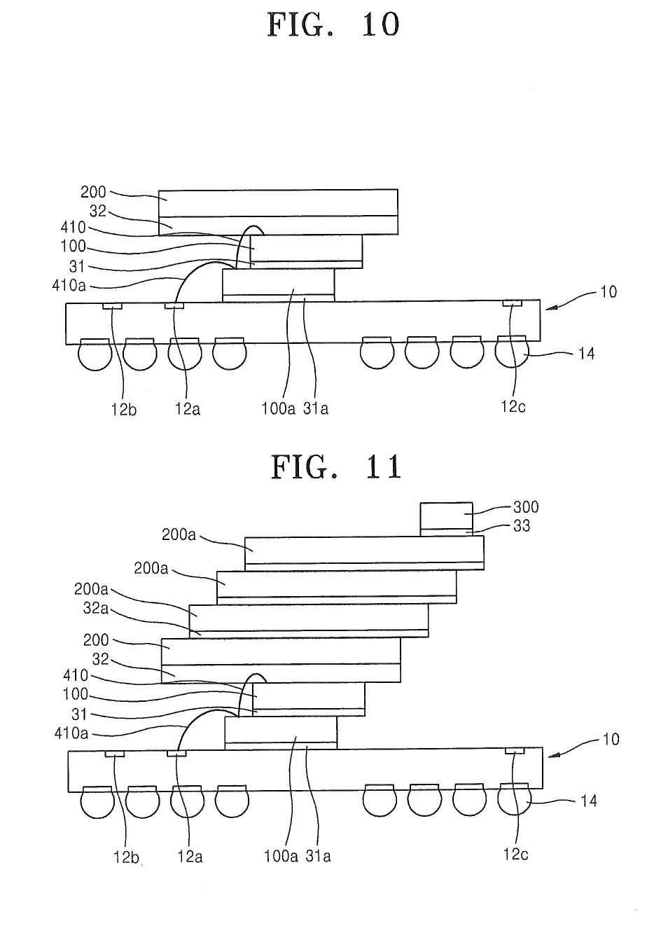

Referring now to FIGS. 2 and 10, the second semiconductor chip 200, in which the second adhesive tape 32 is attached to the lower surface 204 thereof, is attached on the first semiconductor chip 100.

When attaching the second semiconductor chip 200 on the first semiconductor chip 100, the first bonding wire 410 extends from a pad on the upper surface 102 of the first semiconductor chip 100 to the inside of the second adhesive tape 32, and then extends along the lower surface 204 of the second semiconductor chip 200 in a state in which it is spaced apart from the lower surface 204 of the second semiconductor chip 200. The first bonding wire 410 bends in an opposite direction with respect to the lower surface 204 of the second semiconductor chip 200, passes through a pad on the upper surface of the first additional semiconductor chip 100a, and then may be connected to the first finger bond 12a of the semiconductor base frame 10. The first bonding wire 410 and the first additional bonding wire 410a may be located completely below the lower surface 204 of the second semiconductor chip 200.

Referring now to FIGS. 2 and 11, at least one second additional semiconductor chip 200a is stacked on the second semiconductor chip 200 in a stair shape, and then the third semiconductor chip 300 may be additionally stacked on the at least one second additional semiconductor chip 200a. The second bonding wire 420, the second additional bonding wire 420a, and the third bonding wire 430 may be formed after stacking the second additional semiconductor chip 200a and the third semiconductor chip 300.

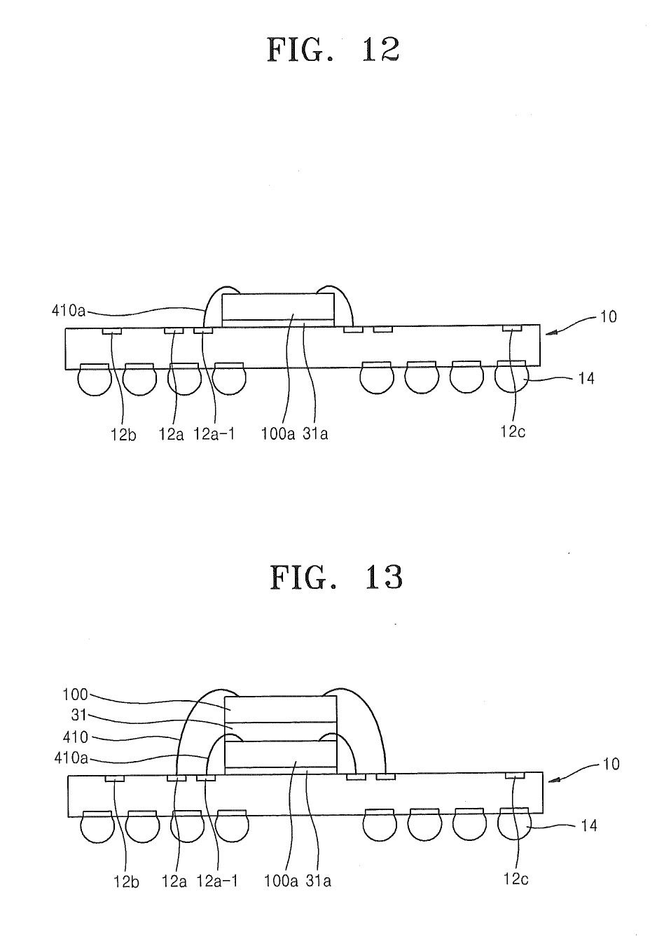

Referring now to FIGS. 12 through 15, cross sections illustrating processing steps in the fabrication of semiconductor packages 1c illustrated in FIG. 3 will be discussed. Referring first to FIGS. 3 and 12, after attaching the first additional semiconductor chip 100a on the semiconductor base frame 10, the first additional semiconductor chip 100a may be connected to the first additional finger bond 12a-1 by forming the first additional bonding wire 410a.

Referring now to FIGS. 3 and 13, the first semiconductor chip 100 to which the first adhesive tape 31 is attached is stacked on the first additional semiconductor chip 100a to overlap the first additional semiconductor chip 100a. The first additional bonding wire 410a is not adjacent to the first semiconductor chip 100 and may penetrate the first adhesive tape 31. The first additional bonding wire 410a may penetrate the first adhesive tape 31, extend to protrude through a lateral side of the first adhesive tape 31, and then be connected to the first additional finger bond 12a-1. The first semiconductor chip 100 may be connected to the first finger bond 12a by forming the first bonding wire 410.

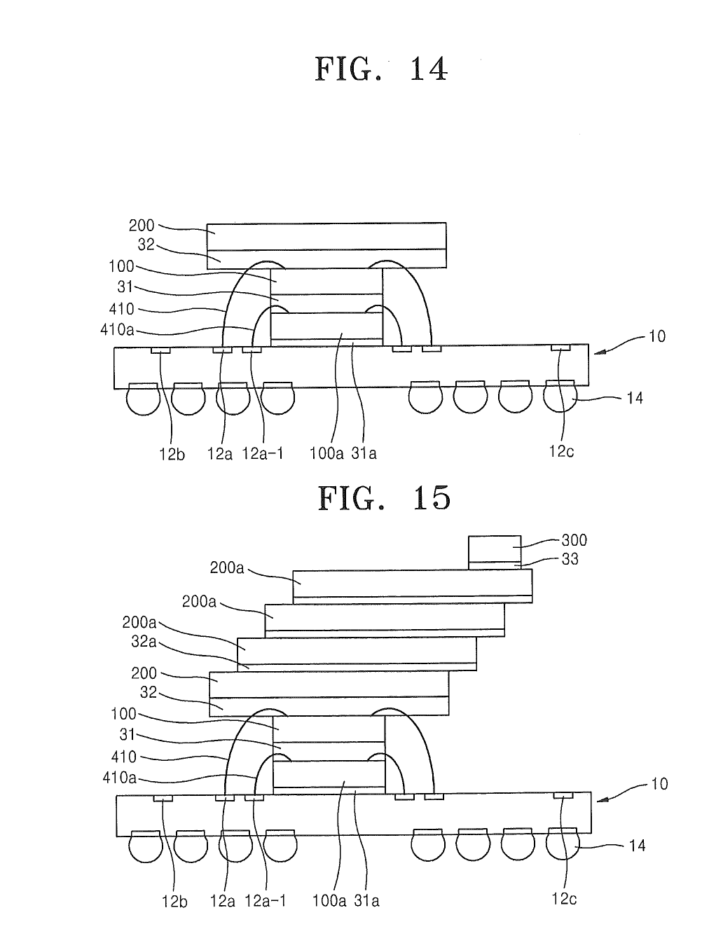

Referring now to FIGS. 3 and 14, after forming the first bonding wire 410, the second semiconductor chip 200, in which the second adhesive tape 32 is attached to the lower surface 204 thereof, is attached on the first semiconductor chip 100. The second semiconductor chip 200 may be stacked on the first semiconductor chip 100 to completely cover the upper surface 102 of the first semiconductor chip 100.

When attaching the second semiconductor chip 200 on the first semiconductor chip 100, the first bonding wire 410 extends from a pad formed on the upper surface 102 of the first semiconductor chip 100 to the inside of the second adhesive tape 32, and then extends along the lower surface 204 of the second semiconductor chip 200 in a state in which it is spaced apart from the lower surface 204 of the second semiconductor chip 200. The first bonding wire 410 bends in an opposite direction with respect to the lower surface 204 of the second semiconductor chip 200, extends to protrude through the lower surface of the second adhesive tape 32, and then is connected to the first finger bond 12a of the semiconductor base frame 10. The first bonding wire 410 may be located completely below the lower surface 204 of the second semiconductor chip 200. Alternatively, only a portion of the first bonding wire 410 may be located below the lower surface 204 of the second semiconductor chip 200.

Referring now to FIGS. 3 and 15, at least one second additional semiconductor chip 200a is stacked on the second semiconductor chip 200 in a stair shape, and then the third semiconductor chip 300 may be additionally stacked on the at least one second additional semiconductor chip 200a. The second bonding wire 420, the second additional bonding wire 420a, and the third bonding wire 430 may be formed after stacking the second additional semiconductor chip 200a and the third semiconductor chip 300.

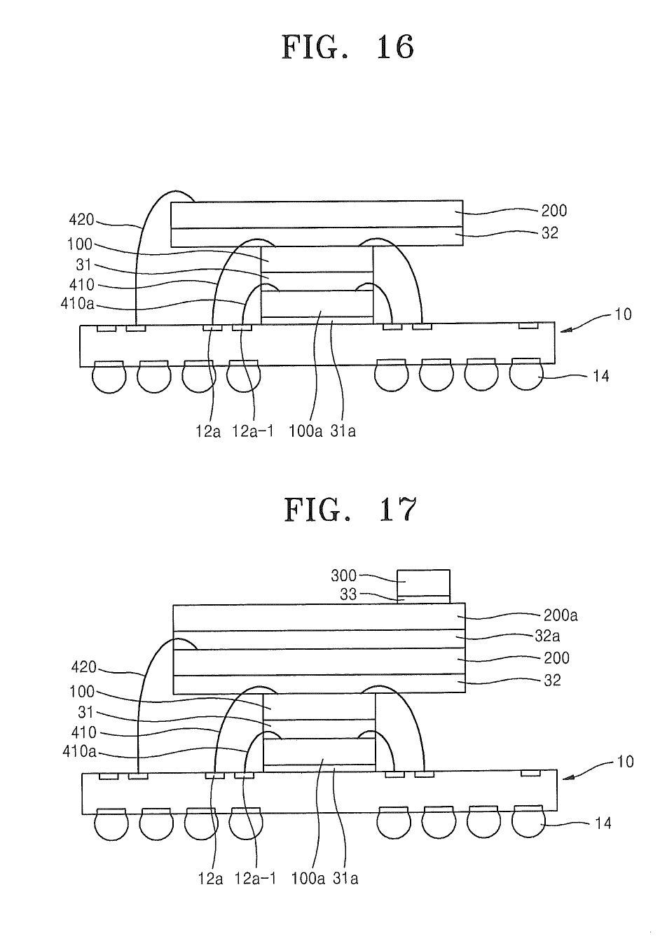

Referring now to FIGS. 16 and 17, cross sections illustrating processing steps in the fabrication of semiconductor packages 1d illustrated in FIG. 4 will be discussed. With respect to FIGS. 16 and 17, descriptions in relation to FIGS. 12 through 14 will not be repeated below.

Referring now to FIGS. 4 and 16, the second bonding wire 420 is formed after stacking the second semiconductor chip 200. As illustrated in FIG. 17, after forming the second bonding wire 420, the second additional semiconductor chip 200a to which the second additional adhesive tape 32a is attached is stacked on the second semiconductor chip 200 to overlap the second semiconductor chip 200. The second bonding wire 420 is not adjacent to the second additional semiconductor chip 200a and may penetrate the second additional adhesive tape 32a. The second bonding wire 420 may pass through a lateral side of the second additional adhesive tape 32a after penetrating the second additional adhesive tape 32a.

The third semiconductor chip 300 may be stacked on the second additional semiconductor chip 200a. The second additional bonding wire 420a and the third bonding wire 430 may be formed after the second additional semiconductor chip 200a and the third semiconductor chip 300.

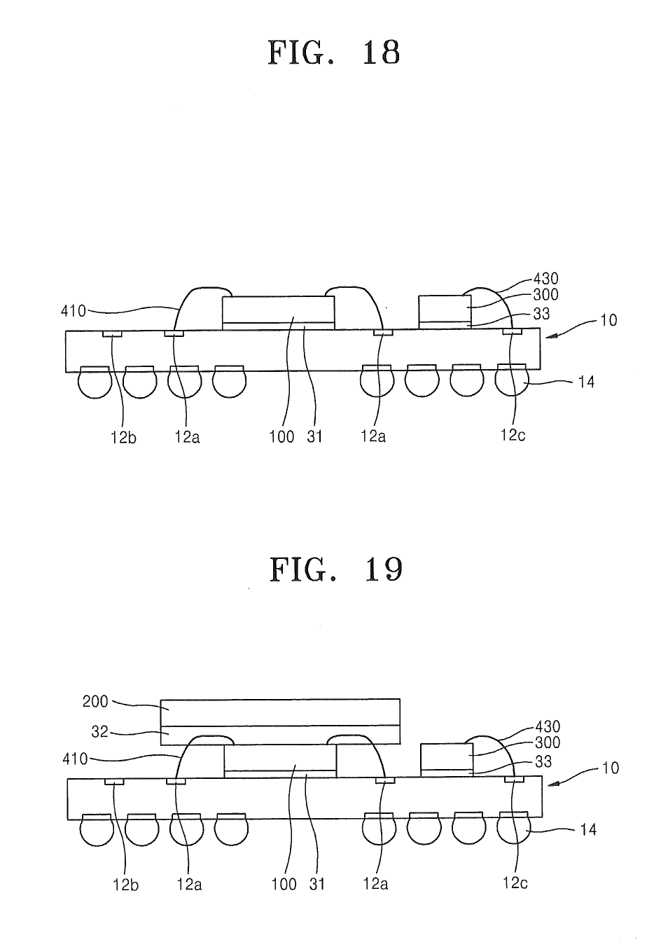

Referring now to FIGS. 18 through 20, cross sections illustrating processing steps in the fabrication of semiconductor packages 1e illustrated in FIG. 5 will be discussed.

Referring now to FIGS. 5 and 18, the first semiconductor chip 100 and the third semiconductor chip 300 are attached on the semiconductor base frame 10. The first bonding wire 410 and the third bonding wire 430 are formed.

Referring now to FIGS. 5 and 19, after forming the first bonding wire 410, the second semiconductor chip 200 to which the second adhesive tape 32 is attached is attached on the first semiconductor chip 100.

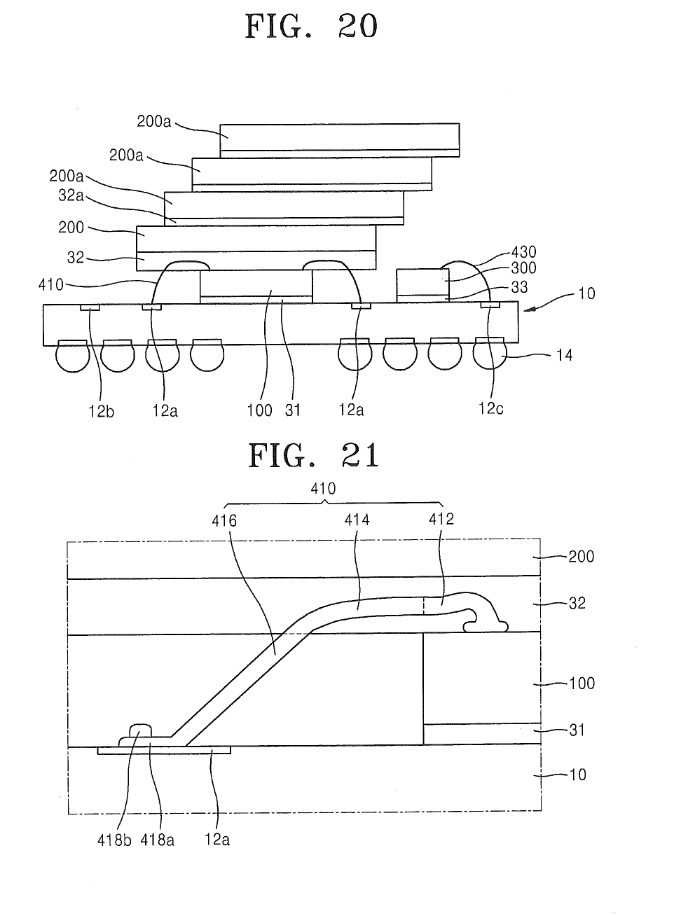

Referring now to FIGS. 5 and 20, at least one second additional semiconductor chip 200a is stacked on the second semiconductor chip 200 in a stair shape. In these embodiments, the at least one second additional semiconductor chip 200a may be stacked so that the third semiconductor chip 300 is disposed in a space under a stack structure that is formed by stacking the second semiconductor chip 200 and the second additional semiconductor chip 200a in a stair shape.

The semiconductor packages 1a, 1b, 1c, 1d, and 1e illustrated in FIGS. 1 through 5 may be used after forming a molding element, which covers all the semiconductor chips 100, 100a, 200, 200a, and 300 and the bonding wires 410, 410a, 420, 420a, and 430, on the semiconductor base frame 10. Although embodiments where the external terminal portion 14 is attached to the semiconductor base frame 10 is illustrated, the external terminal portion 14 may be attached to the semiconductor base frame 10 after forming the molding element without departing from the scope of the present inventive concept.

Referring now to FIG. 21, a cross section illustrating the first bonding wire 410 according to some embodiments of the inventive concept will be discussed. In particular, FIG. 21 illustrates a cross section illustrating a magnification of a portion A of FIG. 1.

As illustrated in FIG. 21, a portion 412, which is located above the upper surface 102 of the first semiconductor chip 100, from among portions 412 and 414 of the first bonding wire 410, which penetrate a second adhesive tape 32, that is, are formed in the inside of the second adhesive tape 32, may have a length shorter than that of the other portion 414, which is not located above the upper surface 102 of the first semiconductor chip 100, from among the portions 412 and 414 of the first bonding wire 410.

In addition, the portions 412 and 414 of the first bonding wire 410, which are formed in the inside of the second adhesive tape 32, and a remaining portion 416 of the first bonding wire 410 may have similar lengths. Through this, a balance of adhesive strength may be maintained between portions in contact with both ends of the first bonding wire 410, that is, between a pad on the upper surface 102 of the first semiconductor chip 100 and the finger bond 12a.

The first bonding wire 410 may be connected to the first finger bond 12a of the semiconductor base frame 10 by forming a stitch bond 418a on the finger bond 12a. Furthermore, the security bump 418b may be further formed on the stitch bond 418a of the first bonding wire 410. The security bump 418b may be a stud bump formed on the stitch bond 418a of the first bonding wire 410 by using a wire bonding method.

In other words, after forming the stitch bond 418a by using a wire that is supplied through a capillary for wire bonding, the first bonding wire 410 is formed by cutting the wire. After forming a stud bump by using a wire that is supplied through the capillary again, the security bump 418b may be formed by cutting the wire again.

The security bump 418b may improve the adhesive strength of the first bonding wire 410 in the first finger bond 12a. The security bump 418b may possibly prevent the adhesive strength of the first bonding wire 410 from weakening in the first finger bond 12a as a force is applied to the first bonding wire 410 when the second adhesive tape 32 in which a portion of the first bonding wire 410 is buried is hardened.

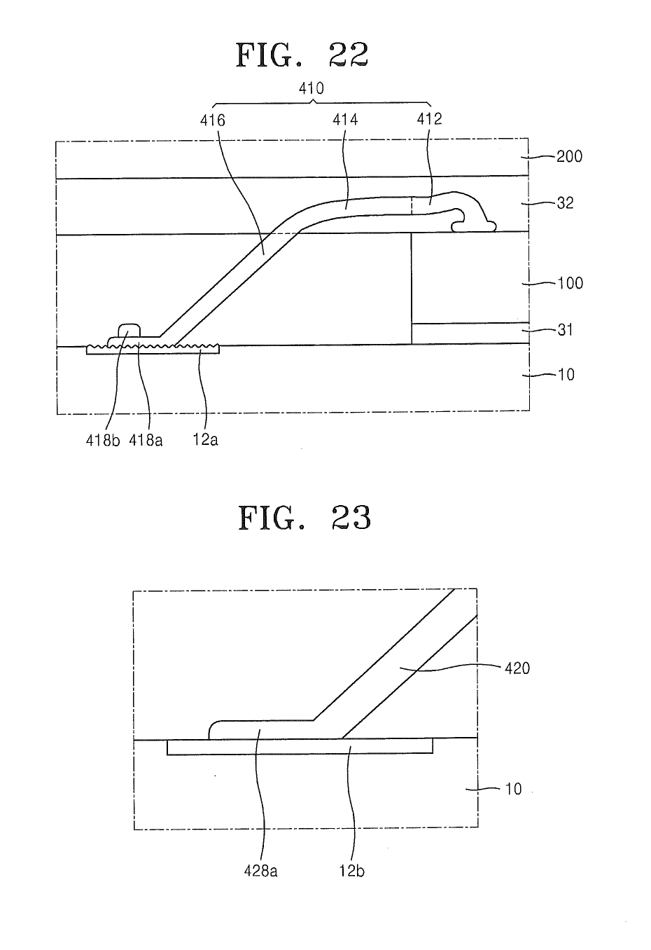

Referring now to FIG. 22, a cross section illustrating the first finger bond 12a, which is connected to the first bonding wire 410, according to some embodiments of the inventive concept will be discussed. In particular, FIG. 22 is a cross section illustrating a magnification of a modification example of a portion A of FIG. 1.

As illustrated in FIG. 22, a roughness may be formed on the surface of the first finger bond 12a. In these embodiments, since an area where the first bonding wire 410 and the first finger bond 12a contact each other increases, the adhesive strength of the first bonding wire 410 may be improved in the first finger bond 12a.

Both the roughness of the first finger bond 12a and the security bump 418b may be formed. Alternatively, the roughness on the surfaces of the first finger bond 12a and the security bump 418b may be selectively formed.

Referring now to FIG. 23, a cross section illustrating the second finger bond 12b, which is connected to the second bonding wire 420, according to some embodiments of the inventive concept will be discussed. In particular, FIG. 23 is a cross section illustrating a magnification of a portion B of FIG. 1.

As illustrated in FIG. 23, the second bonding wire 420 may be connected to the second finger bond 12b of the semiconductor base frame 10 by forming the stitch bond 428a on the second finger bond 12b.

When the bonding wires 410, 410a, 420, 420a, and 430 illustrated in FIGS. 1 through 5 are selectively connected to the finger bonds 12a, 12a-1, 12b, and 12c, the adhesive strength of the first bonding wire 410 in which a ratio of a portion penetrating any one of the adhesive tapes 31, 31a, 32, 32a, and 33 is relatively high, or which passes through the lower surface of one of the adhesive tapes 31, 32, and 33 after penetrating the one of the adhesive tapes 31, 31a, 32, 32a, and 33, may be improved in the first finger bond 12a by using the security bump 418a shown in FIG. 21 and/or the surface roughness shown in FIG. 22. On the other hand, the first additional bonding wire 410a, the second bonding wire 420, and the third bonding wire 430, which do not penetrate the adhesive tapes 31, 31a, 32, 32a, and 33, in which a ratio of a portion penetrating a corresponding one of the adhesive tapes 31, 31a, 32, 32a, and 33 is relatively low, or which pass through the lateral side of the corresponding one of the adhesive tapes 31, 32, and 33 after penetrating the corresponding one of the adhesive tapes 31, 31a, 32, 32a, and 33, may be connected to the finger bonds 12a-1, 12b, and 12c, respectively, by forming only a stitch bond as shown in FIG. 23.

While the inventive concept has been particularly shown and described with reference to exemplary embodiments thereof, it will be understood that various changes in form and details may be made therein without departing from the spirit and scope of the following claims.

What is claimed is:

1. A semiconductor package comprising:
a semiconductor base frame;
a first semiconductor chip on the semiconductor base frame, an upper surface of the first semiconductor chip having a first area;
a second semiconductor chip on the first semiconductor chip, an upper surface of the second semiconductor having a second area larger than the first area;
a first adhesive tape attached to a lower surface of the first semiconductor chip;
a second adhesive tape attached to a lower surface of the second semiconductor chip;
a first bonding wire connecting the first semiconductor chip to the semiconductor base frame; and
a second bonding wire connecting the second semiconductor chip to the semiconductor base frame,
wherein the first bonding wire extends spaced apart from the lower surface of the second semiconductor chip, bends through the second adhesive tape and is connected to a portion of the semiconductor base frame located below the lower surface of the second semiconductor chip.

2. The semiconductor package of claim 1, further comprising:
at least one second additional semiconductor chip stacked on the second semiconductor chip, an upper surface of the at least one second additional semiconductor chip having the second area and an operation speed substantially equal to an operation speed of the second semiconductor chip; and
a second additional adhesive tape attached to a lower surface of the at least one second additional semiconductor chip.

3. The semiconductor package of claim 2, wherein the at least one second additional semiconductor chip has a stair shape on the second semiconductor chip and wherein a thickness of the second additional adhesive tape is less than a thickness of the second adhesive tape.

4. The semiconductor package of claim 2, wherein the at least one second additional semiconductor chip and the second semiconductor chip are lined up in a vertical direction with respect to the semiconductor base frame and wherein the second additional adhesive tape has a thickness substantially the same as a thickness of the second adhesive tape.

5. The semiconductor package of claim 1, further comprising a third semiconductor chip on the second semiconductor chip, the third semiconductor chip having a third adhesive tape connected to a lower surface thereof configured to attach to the second semiconductor chip,
wherein an area of an upper surface of the third semiconductor chip is smaller than the second area and a thickness of the third adhesive tape is less than a thickness of the second adhesive tape.

6. The semiconductor package of claim 5, wherein the first semiconductor chip is one of a static random access memory (SRAM) chip and a dynamic random access memory (DRAM) chip, wherein the second semiconductor chip is a flash memory chip and wherein the third semiconductor chip is a control semiconductor chip configured to control the second semiconductor chip.

7. The semiconductor package of claim 1, wherein an operation speed of the first semiconductor chip is faster than an operation speed of the second semiconductor chip.

8. The semiconductor package of claim 1 wherein one portion of the first bonding wire located above the upper surface of the second semiconductor chip penetrates the second adhesive tape and has a length shorter than a length of a second portion of the first bonding wire.

9. The semiconductor package of claim 1, wherein a thickness of the first adhesive tape is less than a thickness of the second adhesive tape.

10. The semiconductor package of claim 1, further comprising:
at least one first additional semiconductor chip between the first semiconductor chip and the semiconductor base frame, the at least one first additional semiconductor chip having an upper surface having the first area and an operation speed substantially equal to an operation speed of the first semiconductor chip; and
a first additional adhesive tape attached to a lower surface of the at least one first additional semiconductor chip.

11. The semiconductor package of claim 10, wherein the at least one first additional semiconductor chip and the first semiconductor chip are a stair shape and wherein a thickness of the at least one first additional adhesive tape and a thickness of the first adhesive tape are less than a thickness of the second adhesive tape.

12. The semiconductor package of claim 10, wherein the at least one first additional semiconductor chip and the first semiconductor chip completely overlap each other on the semiconductor base frame and wherein the first adhesive tape has a thickness substantially equal to a thickness of the second adhesive tape.

13. The semiconductor package of claim 1, wherein the first bonding wire is below the lower surface of the second semiconductor chip.

14. The semiconductor package of claim 1, wherein the first bonding wire is connected to the semiconductor base frame by a stitch bond on the semiconductor base frame and wherein a security bump is further attached on the stitch bond of the first bonding wire.

15. A semiconductor package comprising:
a first semiconductor chip attached to a semiconductor base frame using a first adhesive tape;
a second semiconductor chip attached to the first semiconductor chip using a second adhesive tape having a thickness larger than a thickness of the first adhesive tape, an upper surface of the second semiconductor chip having an area larger than an area of the first semiconductor chip and an operation speed that is slower than an operation speed of the first semiconductor chip;
a first bonding wire configured to connect the first semiconductor chip to the semiconductor base frame; and
a second bonding wire configured to connect the second semiconductor chip to the semiconductor base frame, wherein the first bonding wire is located below the lower surface of the second semiconductor chip.

16. A semiconductor package comprising:
a semiconductor base frame;
a first semiconductor chip on the semiconductor base frame, an upper surface of the first semiconductor chip having a first area;
a second semiconductor chip on the first semiconductor chip, an upper surface of the second semiconductor chip having a second area larger than the first area;
a first adhesive tape attached to a lower surface of the first semiconductor chip;
a second adhesive tape attached to a lower surface of the second semiconductor chip;
a first bonding wire forming a stitch bond on the semiconductor base frame to connect the first semiconductor chip to the semiconductor base frame; and
a second bonding wire forming a stitch bond on the semiconductor base frame to connect the second semiconductor chip to the semiconductor base frame, wherein a security bump is further attached on the stitch bond of the first bonding wire.
